(19) United States
(12) Patent Application Publication
(10) Pub. No.: US 2005/0184282 A1
(43) Pub. Date: Aug. 25, 2005

(54) Phase change memory cell and method of its manufacture

(76) Inventors: Li-Shyue Lai, Jhube City (TW); Denny Duan-Iee Tang, Saratoga, CA (US); Wen-chin Lin, Hsin-Chu (TW)

Correspondence Address: SLATER & MATSIL, L.L.P., 17950 PRESTON ROAD, SUITE 1000, DALLAS, TX, 75252, US

(21) Appl. No.: 10/783,498

(22) Filed: Feb. 20, 2004

(51) Int. Cl. H01L 47/00

(52) U.S. Cl. 257/4

(57) ABSTRACT

A phase change memory cell includes a resistive heating element for a phase change body that can expeditiously and efficiently heat a portion of the body with the voltage and current usable with MOSFETs. This is achieved through minimizing the area of an interface between a conductive layer and the body by permitting photolithographic techniques to define one dimension of the interface and thin film deposition techniques to define the other dimension.

### TECHNICAL FIELD

The present invention relates to a phase change memory cell and to the method of its manufacture. More specifically, the present invention relates to a memory cell that includes, first, a material capable of having two different temperature-dependent states and, second, facilities for efficiently and expeditiously causing the material to reside in one or the other of those states. The present invention also relates to a method of manufacturing such a memory cell.

### BACKGROUND

Phase change memories are known. See U.S. Pat. No. 6,512,241, issued Jan. 28, 2003 to Lai (“'241” patent) and US Published Patent Application 20030122156 by Maimon, published Jul. 2, 2003 (“'156 application”), the latter containing an extensive list of prior art phase change patents.

Various materials may reside in two or more different states. Two-state devices are favored for digital memories for obvious reasons. Many of these materials exhibit an amorphous state and a crystalline state, transitions between which may be temperature-dependent and, therefore, heat-induced. Typically, the materials exhibit a high electrical resistance when they are in the amorphous state (having a relatively more disordered atomic structure) and a low electrical resistance when they are in the crystalline state (having a relatively more ordered atomic structure). The amorphous or “reset” state represents a logical “0,” while the crystalline or “set” state represents a logical “1.” A phase change element may, accordingly, be viewed as a non-volatile programmable resistor, which reversibly and selectively may be alternated between higher and lower electrically resistive states.

A chalcogenide is an alloy including at least one Group VI element. Chalcogenide alloys have found particular favor as phase change materials in memories. This is due, inter alia, to the facts that the phase changes thereof may be effected expeditiously and reversibly and the difference between the high and low resistance states is typically large. Changes between the amorphous and crystalline states of a chalcogenide may be effected in response to nanosecond-scale changes in the temperature of the material. The resulting differences between high and low resistance of the material may be up to six orders of magnitude.

Numerous chalcogenides suitable for use in memories have been disclosed. These include binary alloys, such as Ga Sb, In Sb, In Se, Sb₂ Te₃ and Ge Te; ternary alloys, such as Ge₂Sb₂Te₅, In Sb Te, Ga Se Te, Sn Sb₂ Te₄ and In Sb Ge; and quaternary alloys, such as Ag In Sb Te, (Ge Sn)Sb Te, Ge Sb(Se Te), and Te₈₁Ge₁₅Sb₂S₂.

Temperature changes in a chalcogenide body of a memory cell are effected by the heating effects (i²r) of a current through a resistive element in proximity with—usually engaging—the chalcogenide body. The resistive element typically comprises an interface between a conductive member and a chalcogenide layer or film. To read the memory cell, a switch element passes current through the chalcogenide, the current level being sensed (high or low) to determine the state (set or reset). The current through the resistive element that sets and resets the memory cell is also controlled by the switch element.

When chalcogenide is in the amorphous, high resistance, reset state, significant current cannot flow therethrough. The chalcogenide may nevertheless be put in its crystalline, low resistance, set state from the reset state if the electrical field therein (and the voltage across it) is sufficiently high. The high field causes so-called Poole-Frenkel conduction which, in combination with the heating effect of an intermediate current flowing through the resistive element—a current that produces significant heat into the material but which is insufficient to melt it—is sufficient to lower the resistance of the chalcogenide, a condition that persists when the voltage and current are cut off and the chalcogenide cools. The duration of the high field and the intermediate current must be sufficiently long to permit nucleation and growth of crystallites within the chalcogenide.

To reset the chalcogenide from the set state, the voltage across it must, again, be sufficiently high to effect Poole-Frankel conduction. A concurrent, sufficiently high current through the resistive element heats an immediately adjacent portion of the chalcogenide above its melting temperature. When the current and voltage are removed, the melted chalcogenide rapidly quenches into its amorphous state.

To read the chalcogenide, a relatively low voltage is applied across the chalcogenide by the switch element. If the chalcogenide is in set state with low resistance, the applied voltage and the resistance of the resistive element limit the current therethrough so that no phase change occurs. The sensing of this current is an indication of a logical “1.” If the chalcogenide is in reset state with high resistance, the current through it is quite small, and sensing that fact is an indication of a logical “0.”

A phase change memory having a number of the foregoing cells may be implemented as (or with) a CMOS integrated circuit (“IC”), as set forth in the foregoing '241 patent and '156 application and in U.S. Pat. No. 6,511,862, issued Jun. 30, 2001 to Hudgens, et al. In this event, the physical size, materials and fabrication procedures for the memory are compatible with CMOS fabrication procedures.

It is known to use a MOSFET as the switch element for controlling current flow through the resistive element and the application of voltage to the chalcogenide body in a memory cell and for sensing or reading the electrical resistance of the chalcogenide body. Thus, the MOSFET may be used to set the cell, rendering the chalcogenide body's resistance low to represent a logical “1,” and reset the cell, rendering the body's resistance high representing a logical “0.” The same MOSFET may serve to apply voltage to, and to transmit current through, the memory cell, the level of the current indicating whether the cell is set or reset.

The switch element must deliver sufficient power to the resistive element to melt (reset) a portion of the chalcogenide. MOSFETs are not optimum switch elements for phase change memories, because they have been reduced in size (reduced channel length and oxide thickness). Accordingly, although current densities through MOSFETs have risen, there is a limit to the voltage that can be applied by a MOSFET to a chalcogenide memory cell before MOSFET breakdown occurs. As a consequence, the area of the interface between the resistive element and the chalcogenide should be made as small as possible, since resistance—and the i²r heating effects of current flowing through the interface—is a function of the area of contact at the interface. Higher resistance at the interface leads to more effective heating of the chalcogenide per unit current. The '241 patent and the '156 published application represent recent prior art attempts to achieve this.

Both of the foregoing two patent documents involve complicated, multi-step deposition and patterning steps to photolithographically define a small conductive area (the resistive element) contacting an overlaying chalcogenide film. The chalcogenide film and a conductive film, a portion of which constitutes the small conductive area, are located on the surface of a substrate on which the switch element, a MOSFET or other transistor, is also located. The chalcogenide and conductive films are more or less vertically overlapped or stacked, and heat flows vertically into the chalcogenide.

### SUMMARY OF THE INVENTION

In one aspect, the present invention provides for a phase change memory cell fabricated by integrated circuit techniques on a semiconductor substrate, which comprises an insulating, dielectric layer on the substrate and a thin conductive film on the dielectric layer. The plane of the film is generally parallel to the plane of the substrate. The dielectric layer supports a layer of a phase change material. The cell further includes an electrically resistive interface between the conductive film and the phase change layer, the interface being defined by an area of engagement between the film and the layer that is generally normal to the plane of the substrate.

In another aspect, the present invention provides for a method of fabricating a phase change memory cell in a substrate by integrated circuit techniques. The method includes forming a thin conductive film on a first dielectric stratum on the substrate, the film being generally parallel to the plane of the substrate and forming a layer of a phase change material on the first stratum so that a terminus of the film and a terminus of the phase change layer have an area of engagement therebetween. The area of engagement is generally normal to the plane of the substrate, wherein an electrically resistive interface is defined by the area of engagement.

In yet another aspect, the present invention provides for a memory cell, which comprises a layer of phase change material, and an elongated thin conductive film having one end engaging a side of the layer to define an interface having a width and a height, at least one dimension (a height) of the interface being determined non-photolithographically by thin film deposition parameters.

In still another aspect, the present invention provides for a method of fabricating a phase change memory cell on a generally planar semiconductor substrate bearing a generally planar ILD layer. The method includes depositing a thin film of a conductive material on the free surface of the ILD, the thin film being generally parallel to the plane of the substrate and having a first terminus, forming a first generally planar IMD layer over the free surface of the thin film, and defining a second terminus of the thin film by forming a trench through the first IMD layer and the thin film. The method further includes filling the trench with a phase change material, a side portion of which has a generally planar interface with the second terminus of the thin film, wherein the plane of the interface is generally normal to the plane of the substrate.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 includes partial top and sectioned side views of a portion of a prior art phase change memory cell according to the prior art as set forth in the '241 patent and the '156 published patent application.

FIG. 2 is a partial schematic representation of a multi-cell phase change memory according to the prior art.

FIG. 3 is a sectioned side view of a phase change memory cell according to an embodiment of the present invention.

FIG. 4 is a magnified view of a portion of FIG. 3 illustrating an improved heat source for a phase change material in the cell of FIG. 3.

FIG. 5 contains a number of sides, sectioned views illustrating the method of fabricating the memory cell of FIGS. 3 and 4.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The product aspects of the present invention relate to an improved phase change memory cell. Preferably, the memory cell is fabricated by integrated circuit techniques and is associated with a transistor, such as a MOSFET, both being on the same substrate. The term “memory cell” refers herein to the memory cell itself and to the memory unit associated with a transistor or other switch-like device. The method aspects of the present invention relate to a method of fabricating the improved phase change memory cell. Preferred embodiments of these aspects will be discussed in the following paragraphs.

In prior art phase change memory cells, a conductive element and a layer of phase change material overlap. The phase change layer is generally parallel to the surface of the substrate. One or more windows are opened through an intervening insulating layer to expose the conductive element. The area of an electrically continuous interface between the conductive element and the phase change layer is determined by the area of the window(s). Thus, the plane of the window(s) and of the interface is parallel to the substrate. The minimum dimensions, and therefore the minimum area, of the window(s) are determined by photolithographic procedures. The window area determines both the electrical resistance of the interface to current flowing perpendicular to the substrate into the phase change layer and the amount of i²r heating of the phase change material that sets or resets it. Thus, the ability to control the i²r heating of the phase change material is limited by photolithography.

The memory cell of the preferred embodiments of the present invention simplifies the formation of the interface between the conductive element and the phase change layer by drastically altering the physical relationship therebetween. This results in the ability to more precisely control the i²r heating of the phase change material.

In the preferred embodiments, the conductive element is a thin film generally parallel to the substrate. The film and the phase change layer do not overlap. Rather, an end of the conductive thin film abuts a side of the phase change layer so that an electrically continuous interface or area of engagement between them is normal to the plane of the substrate. Current flow between the film and the layer is parallel to the substrate. The size of the interface is determined by the width and the height of the conductive film. Photolithographic techniques are followed to make the width of the thin film (parallel to the plane of the substrate) as small as desired. Thin film deposition procedures alone determine the height or thickness of the conductive film (normal to the plane of the substrate). Thin film deposition can produce a film with a height or thickness that is much smaller than the thickness of films produced by photolithographic techniques. Accordingly, the preferred embodiments of the present invention lead to an interface between the film and the layer that is selectively smaller than that achievable by the prior art. The procedures of the prior art required to expose the conductive film are eliminated.

Prior art phase change memory cells may be fabricated by integrated circuit (“IC”) techniques on a substrate. Such a memory cell includes an interface between a layer or body of phase change material and a conductive layer or element. The layers are typically formed generally parallel to the plane of the substrate. The area of the interface determines the resistance thereof to current flow therethrough. Current flow through the interface produces i²r heating which sets or resets the phase change material to low or high resistances. The prior IC techniques position the phase change layer in superjacency to the conductive layer, or vice versa, following a series of complicated photolithographic steps that expose only a small portion of the surface of the conductive layer (or the phase change layer) for engagement with a surface of the phase change layer (or the conductive layer). For a given current, the smaller the area, the more heating of the phase change material occurs. The area of engagement between the films is parallel to the plane of the substrate and current flow therebetween is normal to the substrate.

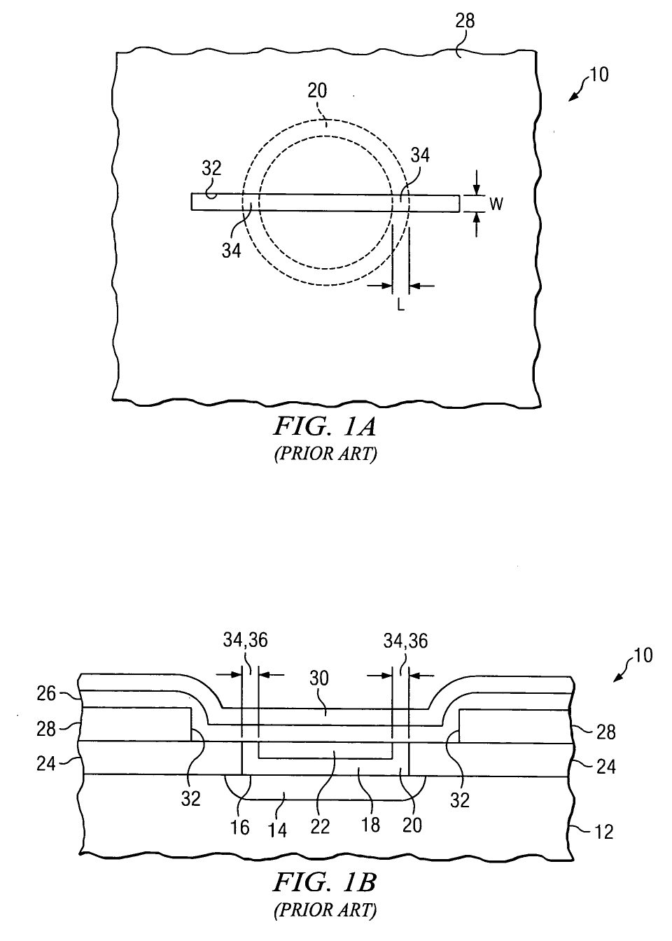

FIGS. 1(A) and (B) respectively depict a partial top view and a sectioned side view of a memory cell 10 according to the prior art. A substrate 12 carries a buried conductive element 14, which may be the drain or source of a MOSFET or the output/input of another transistor or switch-like element (not shown). Electrically connected to the conductor 14 is a lower electrode 16 having the shape of a shallow can with a bottom 18 and a cylindrical sidewall 20. The electrode 16 may be filled with and surrounded by insulating layers 22 and 24. A layer 26 of phase change material is formed over the electrode 16 and over a previously formed glue layer 28. A top electrode 30 is formed over the phase change layer 26.

The glue layer 28 is first formed as a continuum over the insulating layers 22 and 24 and the sidewall 20 of the lower electrode 16. A narrow slit 32 is then opened in the glue layer 28 to expose small portions 34 of the sidewall 20. Accordingly, when the phase change layer 26 is formed, small areas of engagement or interfaces 36 between it and the bottom electrode 16 exist.

The foregoing structure 10 includes elements, such as the glue layer 28 and the slit 32 therein, not present in typical IC structures. The formation of these elements requires the practice of procedures not typically present in the manufacture of a MOSFET. For example, while lower electrodes are commonly formed in fabricating a phase change memory by IC techniques, the formation of the can-shaped electrode 16 is not typical. Its formation requires a conventional conductive metal deposition step, but thereafter requires over-filling the electrode 16 with the insulating layer 22 and then planarizing the electrode 16 layer and the insulating layer 22 so that the sidewall 20 is formed and the insulating material 22 therein is coplanar with the top of the sidewall 20. Exposing the small areas 36 of the sidewall 20 requires deposition of the glue layer 28, formation of a mask (not shown), and opening the slit 32 in the glue layer 28.

Moreover, both the width W and the length L of the interface 36 are limited by photolithographic parameters. Accordingly, photolithography also limits the amount by which the area of the interface 36 can be minimized.

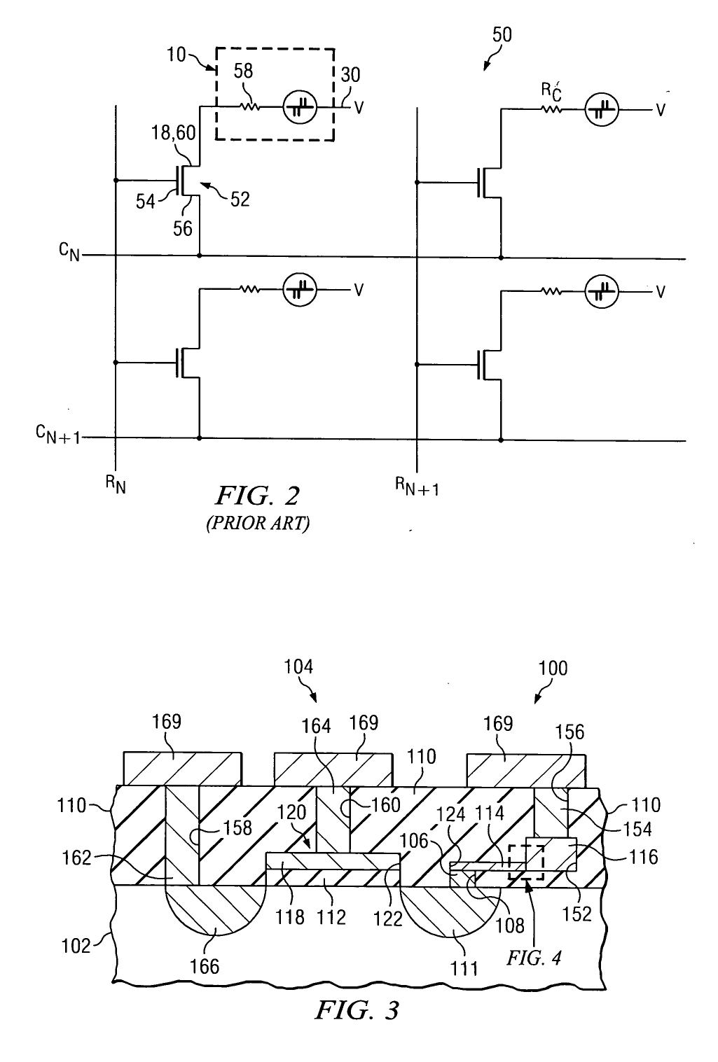

FIG. 2 is a schematic illustration of a part of an IC memory 50 that includes a matrix of memory cells which may be the cells 10 or other cells of the prior art, preferably replaced by the memory cells of the present invention as depicted in FIGS. 3-5. The memory includes MOSFETS 52 or other transistors associated one-for-one with a memory cell 10. Gates 54 of the MOSFETs in the same row are connected to row conductors R_{N}, R_{N+1}, and sources 56 of MOSFETs in the same column are connected to column conductors C_{N}, C_{N+1}.

The conductors R and C are formed in or on a level of the IC memory 50 as are the MOSFETs 52. The resistance of the interface 36 between the sidewall portions 34 and portions of the phase change layer 26 are represented by schematic resistances 58. The upper electrodes 30 are connectable to voltage sources V and the lower electrodes 18 are connected to drains 60 of the MOSFETs 52. The conductors R and C are connectable to appropriate signal sources that selectively effect setting, resetting and reading of the individual cells 10. The operation of the individual cells 10 is described above.

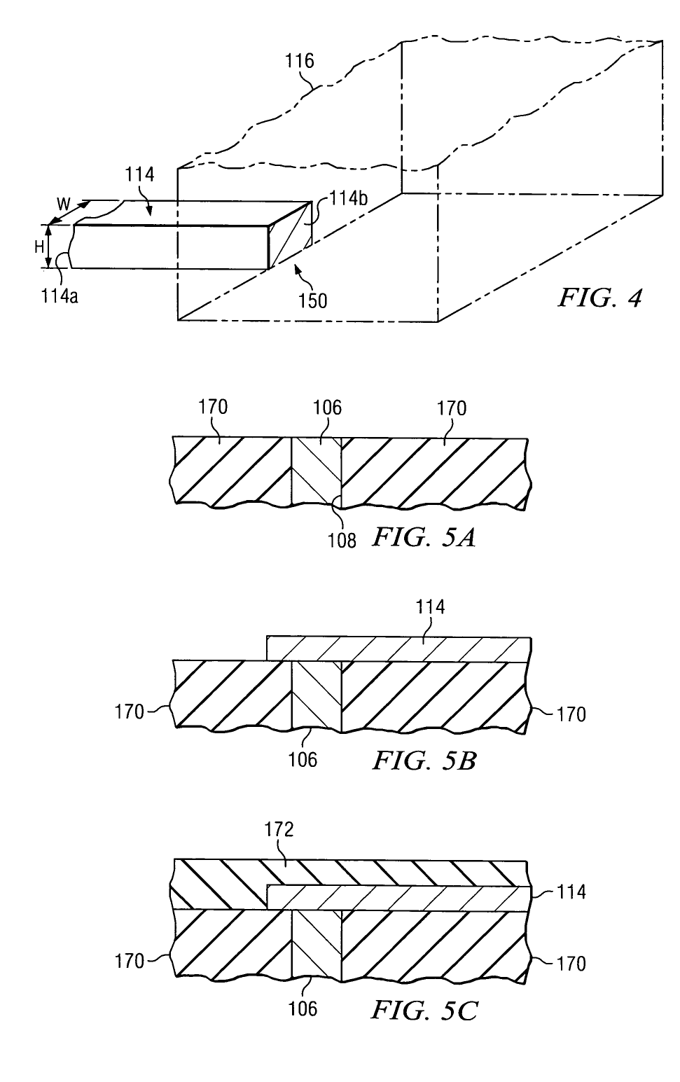

An embodiment of a memory cell 100 contemplated by the present invention is shown in FIGS. 3 and 4. The memory cell 100 may be formed on the same substrate 102 in and on which a MOSFET 104 or other transistor or switch-like device has been formed. The cell 100 and the MOSFET 104 may be associated without deviating from normal IC fabrication procedures.

The memory cell 100 includes a bottom electrode 106 which may be formed in an opening 108 in a dielectric layer 110 on the substrate 102. The electrode 106 is electrically connected to a drain 111 of the MOSFET 104. The dielectric layer 110 is depicted as continuous in FIG. 3, although in reality it may be comprised of numerous strata, some of which are shown in FIG. 4. The opening 108 may be formed simultaneously with the formation of a gate dielectric 112 of the MOSFET 104. Specifically, after deposition of a dielectric layer from which the gate dielectric 112 is formed, the layer is patterned to define the gate dielectric. This same patterning step may form the opening 108. Materials suitable for the conductive layer 108 include Ti, W, TiW, TiN, TiAl, TiAlN, TiWN, as well as other high electrical conductivity materials.

Electrically connected to the lower electrode 106 is a first end or terminus 114a (see FIG. 4) of a conductive thin film 114, the second end or terminus 114b of which will serve to selectively heat a phase change layer 116. Materials suitable for the conductive film 114 include high bandgap, high thermal conductivity materials, such as polysilicon, Si, and SiC. Materials suitable for the phase change layer 116 include the following: an alloy including at least one Group VI element, such as Ga Sb, In Sb, In Se, Sb₂Te₃, Ge Te, Ge₂Sb₂Te₅, In Sb Te, Ga Se Te, Sn Sb₂ Te₄, In Sb Ge, Ag In Sb Te, (Ge Sn)Sb Te, Ge Sb(Se Te), or Te₈₁Ge₁₅Sb₂S₂ alloy, as well as other binary, ternary, or quaternary alloy.

The layer 116 may be formed simultaneously with the formation of a gate electrode 118 of the MOSFET 104, the gate electrode 118 and the gate dielectric 112 constituting a gate 120 of the MOSFET 104. Specifically, the gate electrode 118 may be fabricated by forming an opening 122 in a stratum of the dielectric layer 110 and filling the opening 122 with a conductive material.

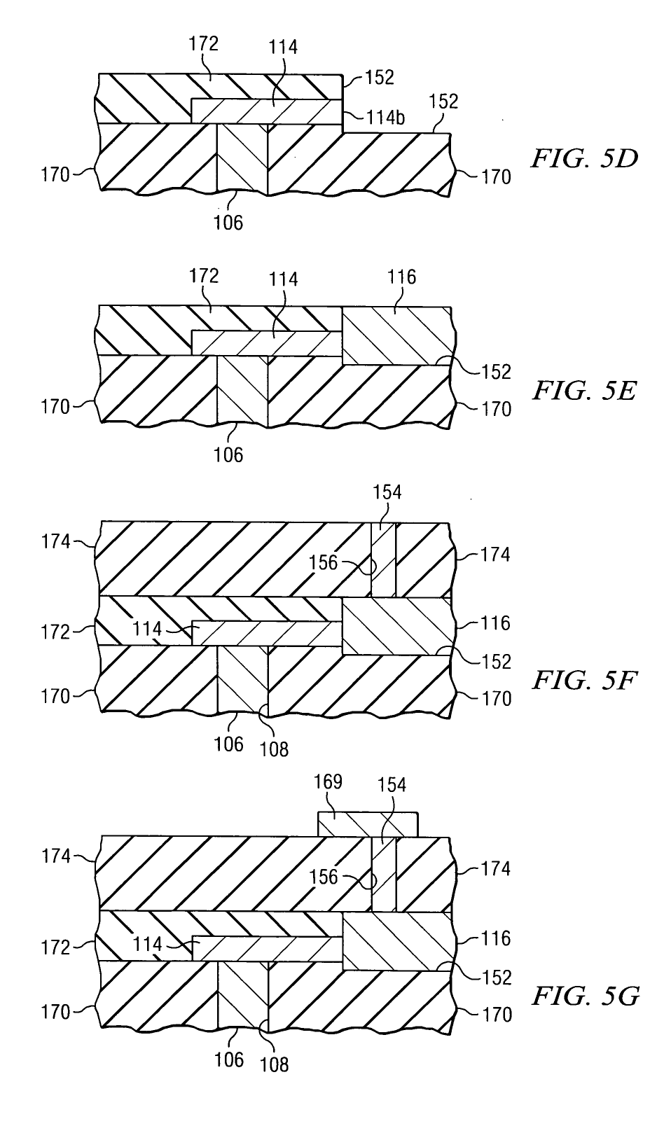

An opening or trench 124 for the thin conductive film 114 may be formed at the same time as the opening 122. The opening 124 is thereafter only partially filled with material to form the thin conductive film 114. Next, the phase change layer 116 is formed, as described more specifically below. The phase change layer 116 and the terminus 114b of the thin conductive film 114 have an area of engagement or interface 150 at which the phase change layer 116 is heated, as described earlier. The phase change layer 116 is formed in a trench 152 in one or more strata of the dielectric 110, as set forth in more detail with respect to FIG. 5.

An upper electrode 154 electrically continuous with the phase change layer 116 is fabricated in an opening 156 formed in a stratum of the dielectric 110. Similar openings 158 and 160 may be simultaneously opened for the electrodes 162 and 164 that are respectively electrically continuous with a source 166 and the gate 120 of the MOSFET 104. Conductive pads 169 electrically continuous with the respective electrodes 154, 162 and 164 may then be formed on a topmost stratum of the dielectric 110.

As noted earlier, in the prior art, the smallest attainable size of engagement between a phase change layer and a conductive layer is limited to the smallest dimension achievable by photolithographic techniques. In FIG. 1(A), the length L of the interface 34 cannot be smaller than permitted by the photolithographic steps that form the sidewall 34, the thickness of which is the length L. Moreover, photolithography limits the minimum size of the width of the slit 32, which is the width W of the interface 36. Accordingly the product of minimum L and minimum W, the minimum area of the interface 36, is limited by lithography.

In embodiments of the present invention, the area of the interface 150 is the product of the width W and the height H of the conductive film 114. While lithography limits the minimum width W of the conductive film 114, lithography does not limit the minimum height H of that film 114. Thus, although the film 114 is formed in the trench 124 that is produced lithographically—which limits the minimum width W of the trench 124—there are no photolithographic limits on the height H of the film 114 because the film 114 is formed as a thin film by thin film formation techniques. Thus, even though the depth of the opening 124 may be the minimum permitted by photolithographic techniques, the height H of the thin film 114 may be significantly less than that depth by terminating thin film-deposition before the opening 124 is filled.

Suitable materials for the thin conductive film 114 are listed above. These materials may be deposited as thin films by any suitable technique that permits a thin film deposit to assume an extremely small height H less than the height achievable by photolithographic procedures. Suitable thin film deposition techniques include physical vapor deposition (“PVD”), such as thermal evaporation and sputtering; chemical vapor deposition (“CVD”), such as low pressure CVD (“LPCVD”) or plasma-enhanced CVD (“PECVD”); atomic layer deposition (“ALD”); and atomic layer chemical vapor deposition (“ALCVD”).

As a consequence of the foregoing, the minimum area W×H of the interface 150 is much smaller than can be achieved in the prior art by strictly photolithographic techniques. This leads to more precise control of both the area of the interface 150 and the amount of i²r heating of the phase change layer 116 effected by a given current.

Referring now to FIG. 5, a process of fabricating the memory cell 100 of the present invention is illustrated. In FIG. 5(a) the lower contact 106 is formed in the opening 108 formed in a lower or first stratum or ILD 170 of the dielectric 110. Next, in FIG. 5(b), the thin conductive film 114 is formed on the ILD 170 by the novel and advantageous combination of photolithographic and thin-film forming (non-photolithographic) techniques, as described above. An intermediate or second stratum or first IMD 172 is then formed over the conductive film 114 and the ILD 170, FIG. 5(c). In FIG. 5(d) a trench or notch 152 is formed through the first IMD 172. This trench formation is effected also through the thin conductive film 114. To ensure that the entire terminus 114b is free to electrically contact the phase change layer 116 (which is next formed in the trench 152, FIG. 5(e)), the trench or notch 152 may partly extend into the ILD 170, FIGS. 5(d) and (e).

In FIG. 5(f) an upper or third stratum or second IMD 174 is then formed over the phase change layer 116 and the first IMD 172, and a top electrode 154 is formed in an opening 156 in the second IMD 174, after which the pad 169 is formed atop the second IMD 174 (FIG. 5(g)).

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A phase change memory cell fabricated by integrated circuit techniques on a semiconductor substrate, comprising:
an insulating, dielectric layer on the substrate;
a thin conductive film on the dielectric layer, the plane of the film being generally parallel to the plane of the substrate;
a layer of a phase change material supported by the dielectric layer; and
an electrically resistive interface between the thin conductive film and the phase change material layer, the interface being defined by an area of engagement between the film and the layer that is generally normal to the plane of the substrate.

2. The memory cell of claim 1, wherein:
the electrical resistance of the interface is inversely proportional to the area of engagement; and
the width of the conductive film generally parallel to the plane of the substrate and the height of the conductive film generally normal to the plane of the substrate determine the area of engagement.

3. The memory cell of claim 2, wherein the width of the conductive film generally parallel to the plane of the substrate is determined by photolithography and the height of the conductive film generally normal to the plane of the substrate is determined by deposition parameters.

4. The memory cell of claim 3, wherein heat produced by current through the interface flows from the interface into the phase change material layer in a direction generally parallel to the plane of the substrate.

5. The memory cell of claim 4, which further comprises a contact on the phase change material layer, wherein:
a current path from the interface into the phase change material layer lies in a direction substantially parallel to the plane of the substrate; and
a current path from the phase change material layer into the contact lies in a direction generally normal to the plane of the substrate.

6. The memory cell of claim 1, wherein the phase change material layer and the thin conductive film are not relatively superjacent or subjacent.

7. The memory cell of claim 6, wherein the phase change material layer resides in a trench formed in the dielectric layer, the bottom surface of the trench and the phase change material layer being coplanar with or below the lower surface of the dielectric layer.

8. The memory cell of claim 7, further comprising a transistor formed in and on the substrate and in the dielectric layer, and wherein an output of the transistor is electrically continuous with one terminus of the thin conductive film, the other terminus of the thin conductive film engaging the dielectric layer to define the interface.

9. The memory cell of claim 8, wherein the transistor is a MOSFET having a gate, wherein the thin conductive film is generally coplanar with a gate electrode of the gate.

10. The memory cell of claim 9, wherein:
the dielectric layer comprises a first, lower stratum, a second intermediate stratum on the first stratum and a third, upper stratum on the second stratum;
the gate electrode and the conductive layer reside on the first stratum, in the second stratum and under the third stratum; and
the phase change material layer resides on the first stratum and in the second and third strata.

11. The memory cell of claim 10, further comprising:
a contact on the gate electrode; and
a topmost stratum on the third stratum, wherein the contact on the phase change material layer and the contact on the gate electrode reside in the topmost stratum.

12. A method of fabricating a phase change memory cell on a substrate by integrated circuit techniques, comprising:
forming a thin conductive film on a first dielectric stratum on the substrate, the film being generally parallel to the plane of the substrate; and
forming a layer of a phase change material on the first stratum so that a terminus of the film and a terminus of the phase change material layer have an area of engagement therebetween, the area of engagement being generally normal to the plane of the substrate, and an electrically resistive interface being defined by the area of engagement.

13. The method of claim 12, wherein the electrical resistance of the interface is inversely proportional to the area of engagement, and which further comprises:
selecting the width of the film parallel to the plane of the substrate and the height of the film normal to the plane of the substrate to determine the area of engagement.

14. The method of claim 13, wherein the width of the film is determined by photolithography and the height of the film is determined by thin film deposition parameters.

15. A method of fabricating a phase change memory cell on a generally planar semiconductor substrate bearing a generally planar ILD layer, comprising:
depositing a thin film of a conductive material on a bottom electrode free surface within the ILD layer, the thin film being generally parallel to the plane of the substrate and having a first terminus;
forming a first generally planar IMD layer over the free surface of the thin film;
defining a second terminus of the thin film by forming a trench through the first IMD layer and the thin film; and
filling the trench with a phase change material, a side portion of which has a generally planar interface with the second terminus of the thin film, the plane of the interface being generally normal to the plane of the substrate.

16. The method of claim 15, further comprising a first electrode within the ILD layer, wherein the thin film is deposited so that its first terminus is in contact with the first electrode.

17. The method of claim 15, wherein the trench is formed partially into the ILD layer.

18. The method of claim 15, wherein heat produced at the interface by the flow of current therethrough flows into the phase change material in a direction generally parallel to the plane of the substrate.

19. The method of claim 18, wherein the conductive material comprises a high bandgap and thermal conductivity material.

20. The method of claim 18, wherein the conductive material comprises polysilicon, Si, or SiC.

21. The method of claim 18, wherein the phase change material comprises a chalcogenide.

22. The method of claim 21, wherein the phase change material comprises a binary, ternary or quaternary alloy.

23. The method of claim 22, wherein the phase change material is selected from the group consisting of Ga Sb, In Sb, In Se, Sb2 Te3, Ge Te, Ge2Sb2Te5, In Sb Te, Ga Se Te, Sn Sb2 Te4, In Sb Ge, Ag In Sb Te, (Ge Sn)Sb Te, Ge Sb(Se Te), Te81Ge15Sb2S2 alloy, and combinations thereof.

24. The method of claim 23, wherein the conductive material comprises polysilicon, Si, SiC, or other high bandgap and high thermal conductivity material.

25. The method of claim 16, which further comprises:
forming a second generally planar IMD layer over the first IMD layer and the free surface of the phase change material; and
forming a second electrode in the second IMD layer and in contact with the free surface of the phase change material.

26. The method of claim 25, wherein the interface, the phase change material and the second electrode are arranged so that a current path into the phase change material from the interface is generally parallel to the plane of the substrate and a current path out of the phase change material into the second electrode is generally normal to the plane of the substrate.

27. The method of claim 26, wherein the first electrode receives the output of a transistor formed in and on the substrate and in the ILD layer.

28. The method of claim 27, wherein the second electrode is connectable to a voltage source.

29. An improved phase change memory cell fabricated by integrated circuit techniques on a substrate, the memory cell being of the type in which there is an interface between a layer of phase change material and a conductive element, the area of the interface determining the resistance thereof to current flow therethrough, wherein the improvement comprises:
the resistive element being a thin film of a conductive material that does not overlap, and extends away from, the phase change material layer in a direction generally parallel to the plane of the substrate, the resistance of the interface being determined by the thickness of the thin film normal to the substrate.

30. The memory cell of claim 29, wherein the interface is defined by the engagement of a side of the phase change material layer and an end of the thin film, the side and the end being generally normal to the plane of the substrate.

31. The memory cell of claim 29, wherein the conductive material comprises a high bandgap and high thermal conductivity material.

32. The memory cell of claim 29, wherein heat produced by current through the interface flows from the interface into the phase change material layer in a direction generally parallel to the plane of the substrate.

33. The memory cell of claim 29, the cell further being of the type in which current flows through the phase change layer from the interface to a contact on the phase change material layer, wherein:
current flows from the interface into the phase change material layer in a direction substantially parallel to the plane of the substrate; and
current flows from the phase change material layer into the contact in a direction generally normal to the plane of the substrate.

34. The memory cell of claim 29, wherein:
the thin film resides on a dielectric stratum on the substrate; and
the phase change material layer resides in a trench formed in the stratum, the trench defining the length of the thin film toward the phase change material layer in a direction generally parallel to the plane of the substrate.

35. The memory cell of claim 29, wherein the width of the thin film generally parallel to the plane of the substrate at the interface is determined by photolithography and the height of the thin film generally normal to the plane of the substrate at the interface is determined by thin film deposition parameters.

36. A memory cell, comprising:
a layer of phase change material; and
an elongated thin conductive film having one end engaging a side of the layer to define an interface having a width and a height, at least one dimension of the interface being determined non-photolithographically by thin film deposition parameters.

37. A method of using the memory cell of claim 36, which comprises applying a voltage across the other end of the film and the layer so that current flows from the interface into the layer generally parallel to the film.

38. The method of claim 37, wherein the current flows out of the layer generally normal to the film.
